(19) United States
(12) Patent Application Publication
(10) Pub. No.: US 2026/0228403 A1
(43) Pub. Date: Aug. 6, 2026

(54) NEURAL GRAPH WITH MACHINE LEARNING TRAINED MODEL FOR CIRCUIT MANUFACTURING

(71) Applicant: NVIDIA Corp., Santa Clara, CA (US)

(72) Inventors: Renaud Gelin, North Vancouver (CA); Karthik Sundararaman, Fremont, CA (US); Kaushik Narayanun, Los Gatos, CA (US)

(73) Assignee: NVIDIA Corp., Santa Clara, CA (US)

(21) Appl. No.: 19/047,233

(22) Filed: Feb. 6, 2025

(51) Int. Cl. G06F 30/327; G06N 3/048; G06N 3/082

(52) U.S. Cl. CPC G06F 30/327; G06N 3/048; G06N 3/082

(57) ABSTRACT

Graph-based mechanisms to model and control the synthesis of circuits on a layer basis, including a deep learning model trained on light-weight graph structures rather than complex circuit designs encoded in collateral files generated by EDA systems, and utilizing graph-based algorithms one the graph structure to determine candidate circuit structures and synthesis processes.

### BACKGROUND

Very large scale integration (VLSI) circuits continue to increase in size and complexity. This creates challenges for meeting design schedules and time-to-market goals for designers and manufacturers of VLSI circuits.

Conventional VLSI workflows may involve many engineering man hours to update VLSI circuits with design enhancements, whether these comprise logical or physical changes to the circuit.

Further complicating the VLSI design process are a myriad of commercial Electronic Design Automation (EDA) tools and systems that may not interoperate well due to semantic differences in file structures, which function as templates and control settings for these tools and systems. The overall VLSI design, manufacture, and test process suffers inefficiencies due to the lack of a common interaction interface between various VLSI implementation and post-silicon phases.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts an example of a circuit synthesis structure.

FIG. 2 depicts an example various collateral files (including view files) for circuit synthesis, organized into databases.

FIG. 3 depicts a VLSI system in accordance with one embodiment.

FIG. 4 depicts an algorithm and system to configure a graph neural network in accordance with one embodiment.

FIG. 5 depicts training of a neural network in accordance with one embodiment.

FIG. 6 depicts an example of a layout and congestion map for a circuit partition.

FIG. 7 depicts gaps between macros and congestion in the circuit partition of FIG. 6.

FIG. 8 depicts a gap network within the circuit partition of FIG. 6.

FIG. 9 depicts the gap network within the circuit partition of FIG. 6 filtered according to congestion and gap size.

FIG. 10 depicts a shortest path from a primary input port to primary output port of the circuit partition of FIG. 6.

FIG. 11 depicts an exemplary physical circuit block comprising a macro component and an IP component.

FIG. 12 depicts a graph structure encoding the component structure depicted in FIG. 11.

FIG. 13 depicts an example of a circuit partition comprising a macro block and test ports.

FIG. 14 depicts a graph structure encoding the block structure of FIG. 11 and the partition structure depicted in FIG. 13.

FIG. 15 depicts the circuit partition of FIG. 13 further comprising a power domain.

FIG. 16 depicts the graph structure of FIG. 14 further encoding the power domain.

FIG. 17 depicts the circuit partition of FIG. 15 further comprising an IP component connected to the test ports.

FIG. 18 depicts the graph structure of FIG. 16 further encoding the IP component connectivity.

FIG. 19 depicts circuit synthesis process stages encoded within a graph structure.

FIG. 20 depicts a graph structure encoding a circuit evolution in accordance with one embodiment.

FIG. 21 depicts a parallel processing unit in accordance with one embodiment.

FIG. 22 depicts a general processing cluster in accordance with one embodiment.

FIG. 23 depicts a memory partition unit in accordance with one embodiment.

FIG. 24 depicts a streaming multiprocessor in accordance with one embodiment.

FIG. 25 depicts a processing system in accordance with one embodiment.

FIG. 26 depicts an exemplary processing system in accordance with another embodiment.

FIG. 27 illustrates an exemplary data center 2700, in accordance with at least one embodiment.

### DETAILED DESCRIPTION

Disclosed herein are embodiments of a centralized, modular, and scalable graph-based system to model the synthesis of VLSI circuits on a layer basis. The system may be utilized to generate a decision graph along and collateral implementation files for configuration and/or control of EDA systems. The system comprises a deep learning model trained on ‘lightweight’ graphs rather than complex VLSI designs themselves. The system may operate more efficiently (e.g., utilizing fewer computing resources and lower human involvement) than conventional design-through-test systems and processes.

The system may also enable improvements in VLSI product quality in terms of power consumption, performance, and area, for example for VLSI products used in data centers and automotive products.

The system may encode a VLSI design into a graph structure. The graph structure may be generated from a transformation of Unified Power Format (UPF), floorplan, and other outputs from EDA systems. Nodes of the graph structure may encode an abstraction layer of a VLSI chip such as top level, synthesis level, intellectual property level, and macro level. The EDA system inputs may be transformed by the system into relationships connecting nodes of the graph structure and into properties of nodes and relationships of the graph structure.

The system may apply graph-based algorithms to the graph structure to determine candidate VLSI circuit architecture solutions and synthesis processes from design to physical test, and may apply a coefficient-and neural network model-based mechanism to filter for the candidate solutions. The system may comprise a machine learning model configured (trained) to adjust the coefficients.

Additional nodes may be added to the graph structure with O(1) complexity. A relationship or property of a node may be changed by parsing the graph structure and applying the changes with O(n) time complexity, where n is the number of nodes in the graph structure.

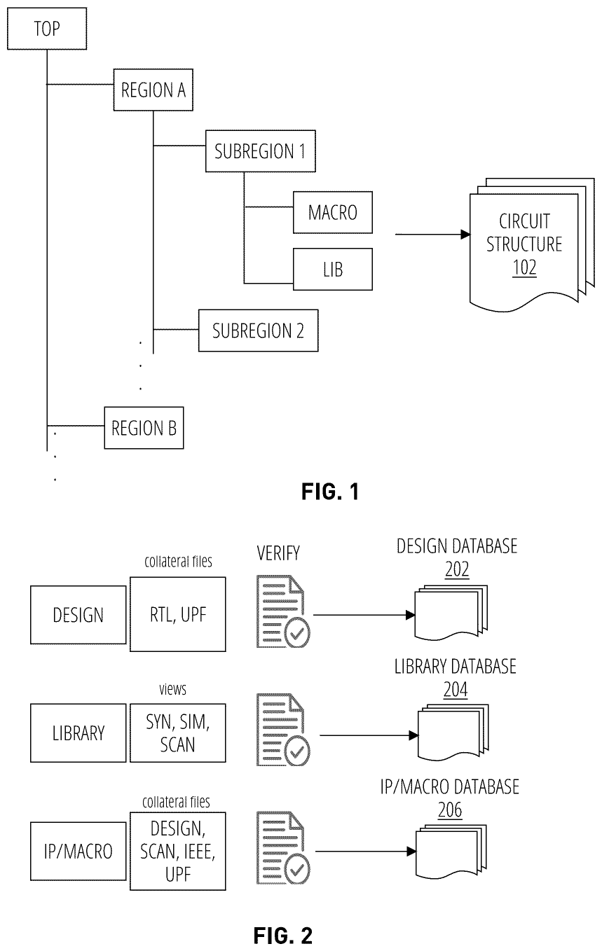

FIG. 1 depicts an example of a circuit structure 102. The circuit structure is organized into a hierarchy of regions, each region comprising particular types of components utilized to synthesize the region. Non-limiting examples of component types include macros, libraries, and intellectual property blocks.

An IP block, or Intellectual Property block, in circuit refers to a reusable unit of logic, cell, or chip layout design that is a pre-designed and pre-verified circuit module. These blocks are used in the development of integrated circuits (ICs) and can include a variety of functionalities, such as processors, interfaces, and memory blocks. IP blocks help streamline the design process by enabling designers to incorporate proven technology into their designs, thus reducing time-to-market, costs, and risks associated with developing the blocks from scratch. They are often licensed from third-party vendors and can be delivered as soft IP (synthesizable RTL) or hard IP (physical layout).

A macro refers to a predefined, reusable block or module that encapsulates a specific circuit function or design. Macros often comprise multiple interconnected components, such as transistors, gates, or more complex functional units, and are used to simplify the design process by promoting reuse and consistency across different parts of the design. They often represent commonly used functions or patterns, such as arithmetic units, memory blocks, or communication interfaces, and may be parameterized to adapt to different design requirements. Macros streamline the design process, reduce errors, and improve productivity in complex circuit designs like those used in integrated circuits.

A component library is a collection of pre-defined models and symbols representing electronic components such as resistors, capacitors, and integrated circuits. These libraries are used to streamline the design process by providing designers with readily available components that may be easily incorporated into circuit schematics and layouts. This ensures consistency, accuracy, and efficiency in the design process by enabling engineers to focus on circuit functionality rather than on creating component models from scratch.

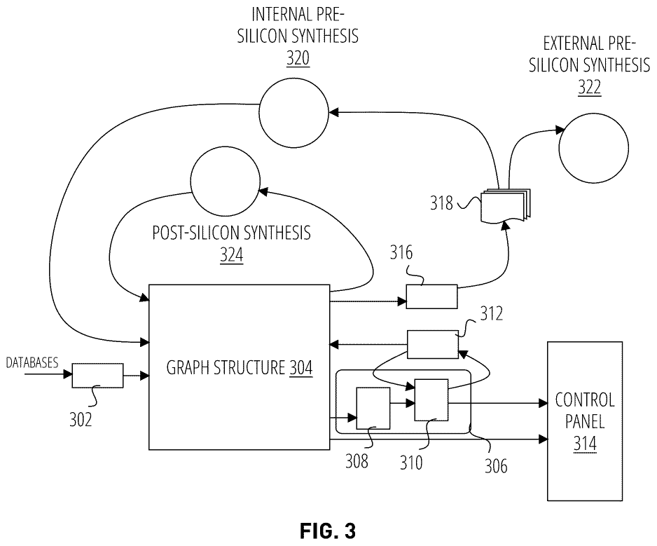

FIG. 2 depicts an example of collateral files (including view files) that may be used during circuit synthesis, organized into databases. Collateral files encode the characteristics of the circuit or components of the circuit, and may be generated by Electronic Design Automation tools/systems or, for components supplied by third parties, provided by the suppliers of the components (e.g., IP components).

One example of a collateral file is an RTL file. An RTL (Register Transfer Level) file is used in circuit synthesis to describe the design of a digital circuit at a higher abstraction level. It specifies the operations, the data flow between registers, and how data is transformed within a digital system using a hardware description language, such as Verilog or VHDL.

During synthesis, the RTL file is converted into a gate-level representation, where Boolean expressions and logic gates are generated to implement the specified behavior. This process enables the design to be translated from a high-level description to a physical implementation on a hardware platform, such as an FPGA or ASIC.

Another example of a collateral file is a UPF file. A UPF (Unified Power Format) file is used in circuit synthesis to define power intent for electronic design, particularly in low-power designs. It provides a standardized way to specify power domains, voltage levels, power states, and the power management strategies required for the design. This enables power constraints and requirements to be consistently applied across different stages of the design and verification processes.

Another example of a collateral file is a SYN file. A Synthesis (SYN) file comprises constraints and directives for a circuit synthesis tool. It may specify details such as timing constraints, area optimization goals, and other design guidelines that influence how the synthesis tool converts a high-level description (e.g., from hardware description languages like VHDL or Verilog) into a gate-level representation. This file essentially guides the synthesis process to meet specific performance and resource utilization requirements.

Another example of a collateral file is a SIM file. A Simulation (SIM) file is used in circuit synthesis and simulation to define a circuit's parameters, configuration, and behavior. It typically contains simulation commands, component models, and netlist information necessary to simulate the electrical behavior of circuits in a simulation environment. These files allow engineers to test and verify circuit designs before physical implementation, facilitating the optimization of circuit performance and the identification of potential issues.

Another example of a collateral file is a SCAN file. In circuit synthesis, a SCAN file is typically used for scan chain insertion, a step in design-for-testability (DFT) techniques. The SCAN file provides information regarding how flip-flops in a digital circuit are converted into scan flip-flops, enabling efficient testing of sequential circuits. It defines the configuration of scan chains—sequentially connected flip-flops that can shift test data in and out—thereby facilitating easier detection and diagnosis of faults in the circuit. This file is useful for enabling scan-based testing methodologies such as stuck-at fault testing and transition fault testing.

The purpose and content of other file types, such as DESIGN and IEEE, are readily understood by those of ordinary skill in the art.

The various collateral files may be parsed and organized into databases, e.g., a design database 202, a library database 204, and an IP/Macro database 206.

FIG. 3 depicts a VLSI synthesis system in accordance with one embodiment. The various databases comprising the settings, constraints, and characteristics of the collateral files are processed through a graph generator 302 to generate a particular type of graph structure 304. Particulars of the graph structure 304 in one example are described in later Figures.

The graph structure 304 is processed through a neural network configurator 306 comprising a filter 308 to produce a filtered graph 310 structure (also referred to herein as a ‘catalogue’) suitable for training (configuring) a neural network 312 to generate such filtered graphs 310 and graph structures 304 for synthesis of other circuits. The filter 308 may remove redundant features from the graph structures 304 so that the filtered graph 310 may be encoded into smaller (e.g., lower dimensionality) tensors than the graph structures 304, resulting in more efficient training of the neural network 312.

The neural network 312 may comprise a graph neural network configured to embed the filtered ‘lightweight’ graph structure generated by the neural network configurator 306. Structures for graph neural networks suitable for use in the neural network 312 are known in the art.

The filtered graph 310 may also be provided to a control panel 314 for use by a human operator of the system, e.g., to provide continuous updates of the circuit synthesis life cycle.

The graph structure 304 may be processed through a transformer 316 to generate collateral files 318 utilized in internal pre-silicon synthesis 320 and external pre-silicon synthesis 322, where ‘internal’ and ‘external’ refer to within or external to a particular organization, respectively. The transformer 316 may comprise graph traversal mechanisms known in the art, to transform node and edge properties of the graph structure 304 into structured properties encoded in the collateral files 318.

The graph structure 304 may also be applied to guide post-silicon synthesis 324 of the circuit, and feedback from the post-silicon synthesis 324 processes may be utilized to update the graph structure 304 for improving the training/configuration of the neural network 312. The post-silicon synthesis 324 may obtain/extract process settings, constraints, and characteristics from the graph structure 304 using known graph-traversal algorithms.

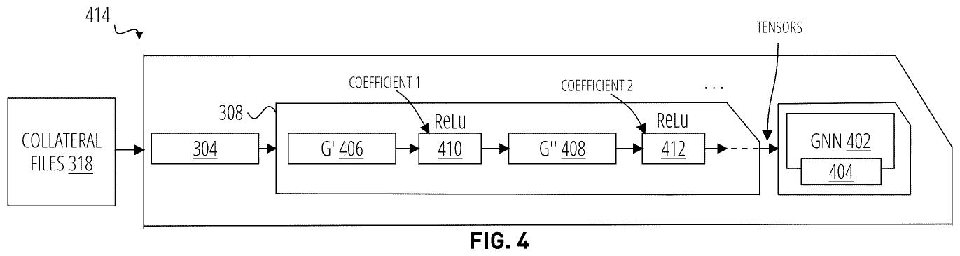

FIG. 4 depicts an algorithm and system to configure a graph neural network in accordance with one embodiment. The collateral files 318 are processed through a filter 308 to generate the filtered graph 310, which may be encoded into tensors to query or train an endpoint graph neural network 402 component of the overall neural network 312. The graph neural network 402 transforms the tensors into a graph embedding 404 in manners known in the art. The tensors output from the filter 308 may encode a filtered and simplified version of the input graph structure 304.

The filter 308 may comprise a number of filtering layers (two such layers are depicted), e.g., each comprising a graph neural network 406, 408 and a filter activation 410, 412. The activation layers, e.g., ReLu layers, may each configured with activation coefficients that are trained using the output predictions of the neural network 312.

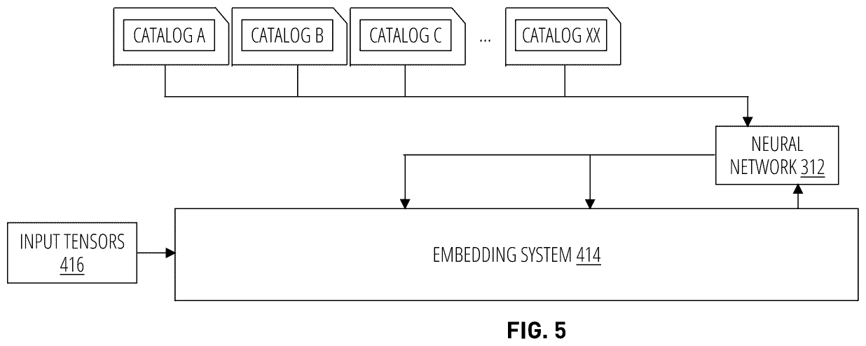

FIG. 5 depicts training of a neural network in accordance with one embodiment. The

system comprises a neural network 312, an embedding system 414, and an input tensors 416. Catalogues from past projects may be applied to train the neural network 312 to predict the coefficients applied by the layers of the neural network configurator 306.

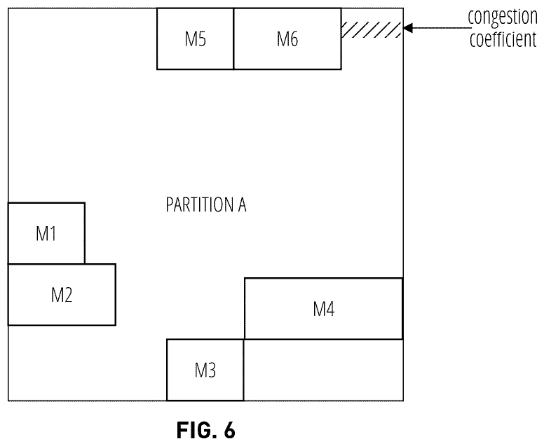

FIG. 6 depicts an example of a layout and congestion map for a circuit partition. The map may for example take the form of an IEEE DEF (Design Exchange Format) file or an industry-standard LEF (Library Exchange Format) file.

LEF refers to a data format used for exchanging integrated circuit design data between different computer-aided design (CAD) tools. It is specifically governed by the IEEE and used widely in Electronic Design Automation (EDA) processes. DEF files may comprise detailed information about the physical layout of an integrated circuit, including components, pins, nets, and the placement and routing data necessary for manufacturing. This format facilitates interoperability between tools from different vendors and helps ensure consistent design data translation throughout the design and production pipeline.

LEF (Library Exchange Format) is an industry standard format developed by Cadence Design Systems, Inc. for representing the physical layout of integrated circuits. It describes the geometric and logical layout information of the standard cells used in VLSI (Very Large Scale Integration) design. LEF specifies layer definition, which specify the layers used in the circuit synthesis process and their characteristics. LEF may also specify a layout of each cell in a circuit, including its size and the positions of pins and obstructions. LEF may also specify design rules and constraints for the standard cells utilized in a circuit. LEF files may be applied in conjunction with DEF files to facilitate the physical design flow of a circuit, enabling the interchange of data between different EDA (Electronic Design Automation) tools.

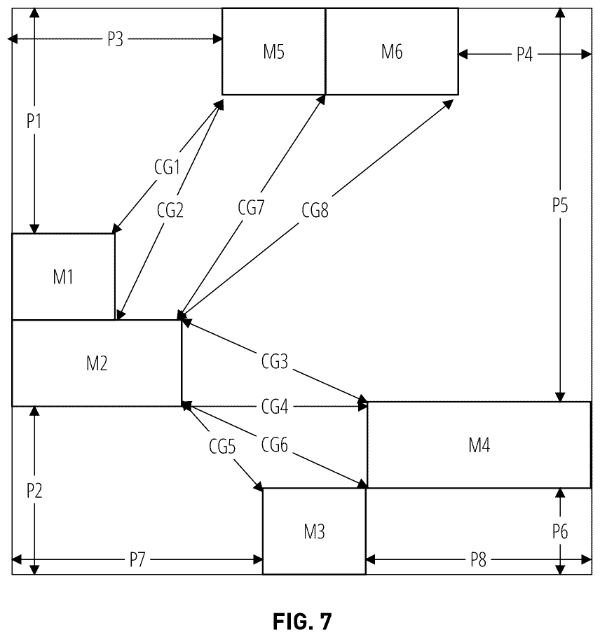

An exemplary process for transforming the various collateral files into a graph structure 304 is depicted in FIG. 7-FIG. 10.

FIG. 7 depicts the identification of partition gaps (Pₙ) and core gaps (CGₙ) between macros (Mₙ) of the circuit of FIG. 6. Gaps (the separation along coordinate axes) between macros may be parameterized by coefficient 1 (see filter 308). Gaps (Pₙ and CGₙ) present in the design-based macro coordinates include the gap width (Coefficient 1) and gap congestion information (Coefficient 2).

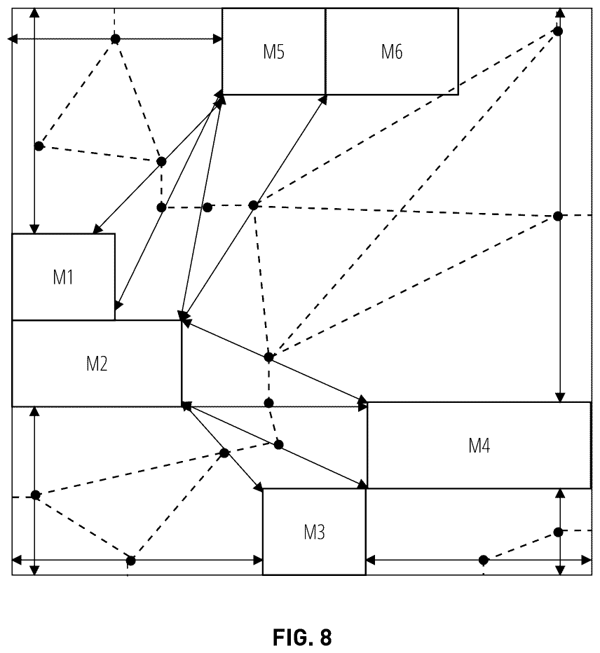

FIG. 8 depicts a gap network (dashed lines) within the circuit partition of FIG. 6. The distance between midpoints (black circles) of the macro corner-to-corner gaps, and between the midpoints of the gaps (CG values) and the midpoints of separations of the macros along coordinate axes (P values) may be derived from the gap network.

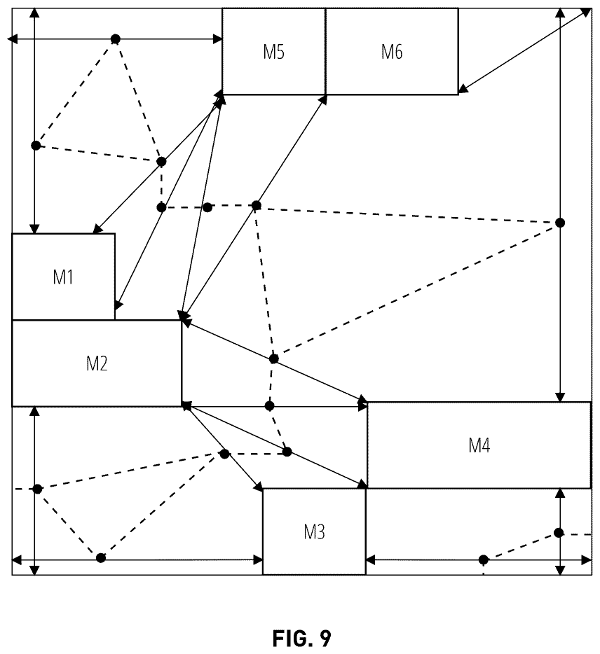

FIG. 9 depicts the gap network within the circuit partition of FIG. 6 filtered according to congestion and gap size. Nodes and edges are filtered from the graph structure 304 based on gap width and gap congestion metrics in the corresponding region of the circuit, e.g., partition. The filtering may be performed for example using Rectified Linear Unit (ReLu) activation layers in the filter 308, for example.

The filter 308 removes nodes and edges from graph structure 304 that do not satisfy a configured threshold condition. An example of such a condition is that if the space between two macros (gap) of a partition is too small to route a data bus that is N-bits (metal tracks) wide, then the corresponding nodes and relationships are removed from the graph structure 304.

An example of such a condition is that if the congestion of a gap is already too high to route a N-bit wide data bus, then the corresponding nodes and relationships are removed from the graph structure 304.

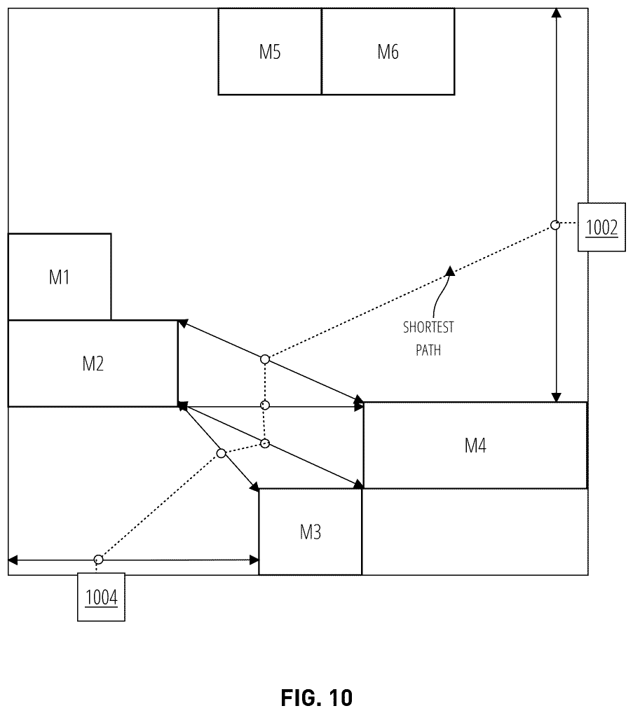

FIG. 10 depicts a shortest path (dotted line) from an input port 1002 to an output port 1004 of the partition of FIG. 6. This shortest path may be derived from the (filtered) gap network of the partition using any of the known varieties of shortest-path algorithms.

The graph structure 304 encodes, among other things, characteristics such as circuit and features, features of products that incorporate the circuit, circuit synthesis process parameters, and versioning information. These categories may be encoded in the graph structure 304 by different types of nodes and relationships.

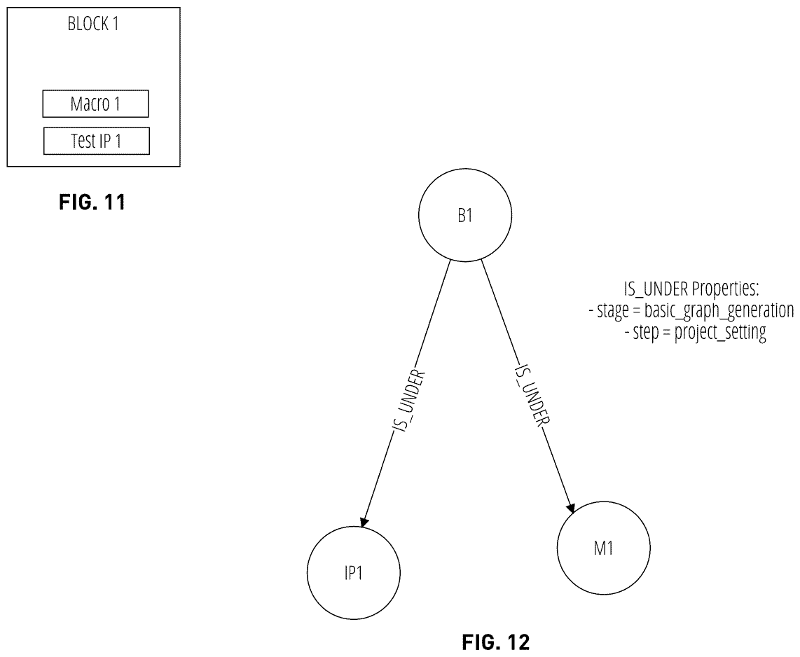

FIG. 11 depicts an exemplary physical circuit block (block 1) comprising a macro component (Macro 1) and an IP component (Test IP 1). The block and its constituents may be encoded in the graph structure 304 as component nodes B1 (Block 1), IP1 (Test IP1), and M1 (Macro 1). The names and encoding symbols utilized are of course mere examples. These physical circuit features may be encoded in the graph structure 304 as a hierarchy of component nodes. The physical hierarchy of components may be encoded in the graph structure 304 using types edges, e.g., edges typed as IS_UNDER for children of a containing component. See FIG. 12.

Component nodes encode a circuit's physical levels, macros, IP blocks, and internal pins. The component nodes may distinguish the type of physical feature they represent using a type property.

Component nodes may further comprise a function property that encodes a function of the component. For example, this property may indicate that the node functions at a design level, or functions as a phase-locked loop, or functions as a test codec. Component nodes may further comprises additional properties such as a module name, a hierarchical instance name, and so on. The component node may also encode power elements of the circuit.

The graph structure 304 may also encode placement parameters for circuit components. Placement parameters may be encoded for example by index position nodes. Index position nodes may comprise properties including the X coordinate and Y coordinate of a component's placement, which may be global coordinates for the entire design, or coordinates relative to a containing component. Index position nodes may be utilized during the determination of the relative placement of each component compared to others and further enables a determination of distances utilized in congestion and shortest path estimations. Distances may also be utilized to guide certain design decisions such as a number of pipeline stages needed in parts of the circuit.

The graph structure 304 may utilize a typed edge to encode the position of component corners as index positions. For example a connection between a component node and the corner of a component with an edge comprising an IS_POSITIONED type.

The graph structure 304 may encode interfaces to, from, and between the physical layers using a particular type of node, e.g., an “IO” node. An IO-type node may comprise properties such as signal flow direction, function, and X and Y coordinates (global or relative). An IO node may comprise additional properties than these, according to the specific implementation. Each interface encoded in the graph structure 304 may be related with at least a component position index node or another IO node. This relation may be encoded for example with an IS_LOCATED edge type.

The graph structure 304 may encode a connection between an interface encoded by an IO node and a component using a particular edge type, e.g., a ROUTE type edge.

FIG. 12 depicts a exemplary graph structure encoding the component structure depicted in FIG. 11. The various nodes may comprise the following properties:

### B1 Component Node Properties

type=Block
function=design
module_name=B1
hier_instance_name=.

### M1 Component Node Properties

type=Macro
function=PLL
module_name=M1
hier_instance_name=macro1_inst

### IP1 Component Node Properties

type=IP
function=Test IP
module_name=IP1
hier_instance_name=ipl_inst

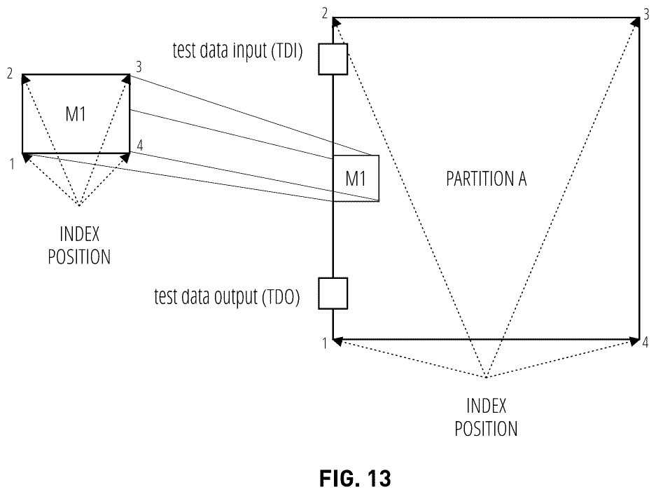

FIG. 13 depicts an example of a circuit partition comprising a macro block M1 and test ports (input port TDI and output port TDO). Index values are assigned to the corner positions of the macro block in the partition. The partition also has index values assigned at the corner points, in the same relative arrangement as for the contained macro block M1.

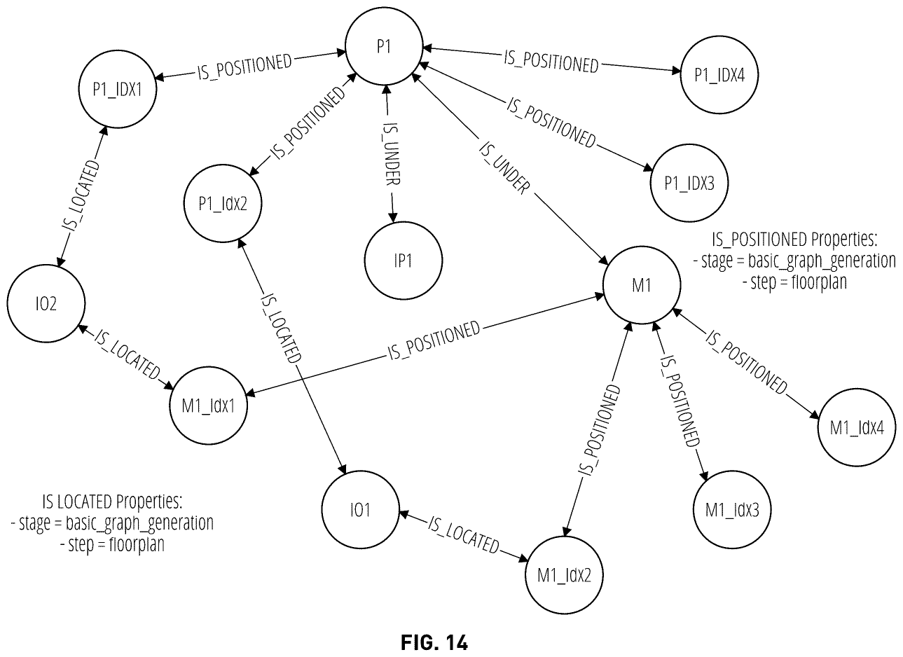

FIG. 14 depicts a graph structure encoding the partition layout depicted in FIG. 13 (and including the Test IP block of FIG. 11). The graph structure comprises index position nodes (denoted with IDX) for each of the partition (P1) and the macro block (M1). The graph structure further comprises IS_LOCATED edges indicating interfaces to the macro block and partition from the TDI port (IO1) at index 2 (for each), and to the TDO port at index 1 (for each):

### P1_IDX1 Node Properties

x_coordinate=X_{P1_1}
y_coordinate=Y_{P1_1}

### P1_IDX2 Node Properties

x_coordinate=X_{P1_2}
y_coordinate=Y_{P1_2}

### P1_IDX3 Node Properties

x_coordinate=X_{P1_3}
y_coordinate=Y_{P1_3}

### P1_IDX4 Node Properties

x_coordinate=X_{P1_4}
y_coordinate=Y_{P1_4}

### M1_IDX1 Node Properties

x_coordinate=X_{M1_2}
y_coordinate=Y_{M1_2}

### M1_IDX2 Node Properties

x_coordinate=X_{M1_2}
y_coordinate=Y_{M1_2}

### M1_IDX3 Node Properties

x_coordinate=X_{M1_3}
y_coordinate=Y_{M1_3}

### M1_IDX4 Node Properties

x_coordinate=X_{M1_4}
y_coordinate=Y_{M1_4}

### IO1 Node Properties

name=i_tdi
x_coordinate=x1
y_coordinate=y1
direction=in
function=TDI

### IO2 Node Properties

name=o_tdo
x_coordinate=x2
y_coordinate=y2
direction=out
function=TDO

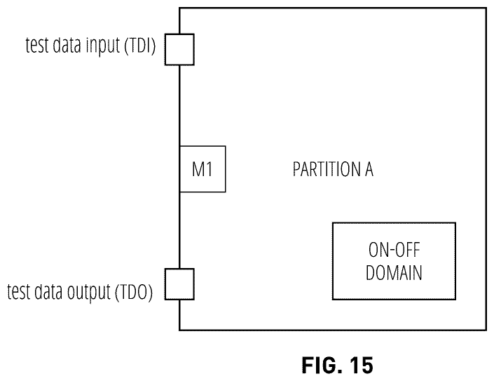

FIG. 15 depicts the circuit partition of FIG. 13 further comprising a power domain (a component block).

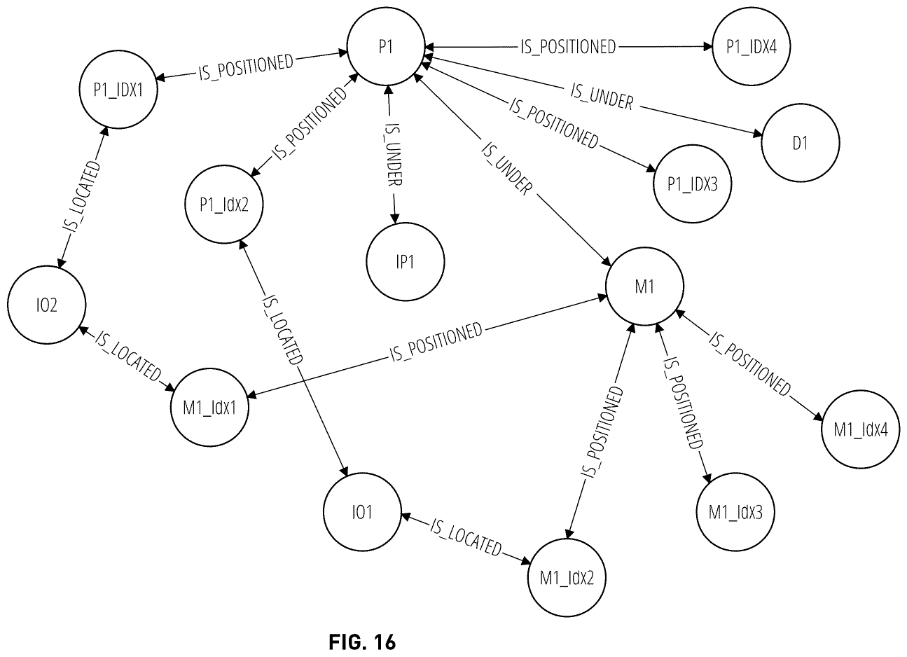

FIG. 16 depicts the graph structure of FIG. 14 further encoding the power domain in the component hierarchy (node D1).

### P1 Component Node Properties

type=block1
function=design
module_name=B1
hier_instance_name=.
power_domain=Always-On

### D1 Component Node Properties

type=block2
function=design
module_name=D1
hier_instance_name=/a/di_on_off_inst
power_domain=On-Off

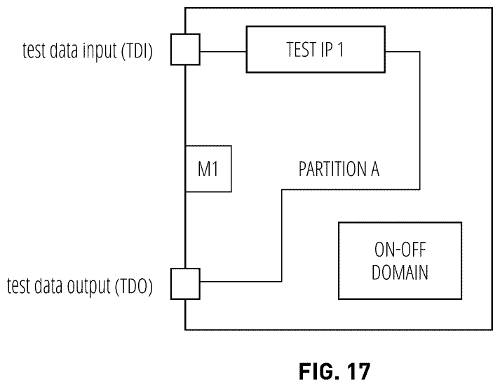

FIG. 17 depicts the circuit partition of FIG. 15 further comprising an IP component (TEST IP 1) connected to the test ports.

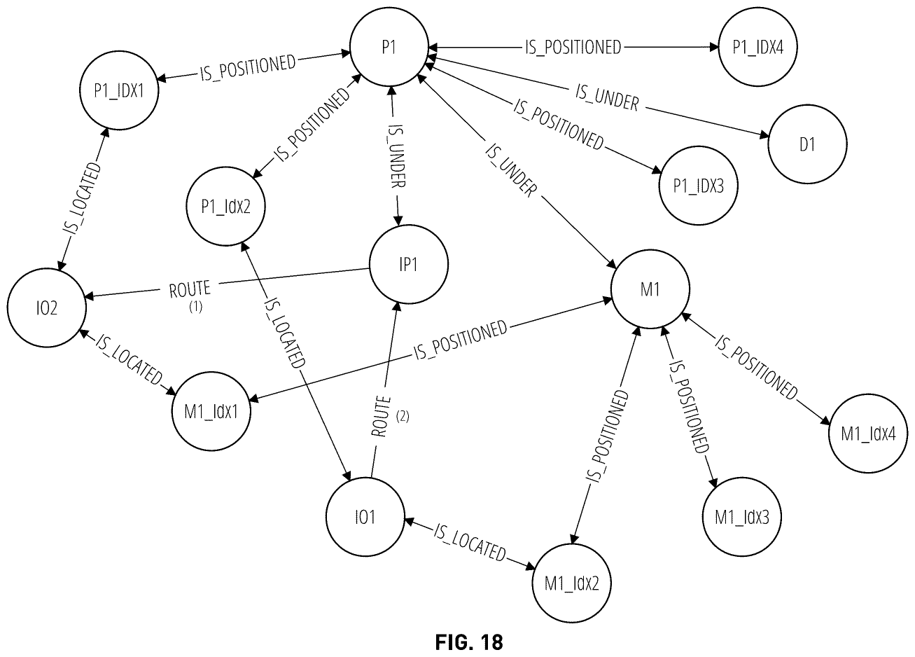

FIG. 18 depicts the graph structure of FIG. 16 further encoding the IP component connectivity.

### Route (1) Properties

stage=basic_graph_generation
step=control_ip_and_network
distance=20

### Route (2) Properties

stage=basic_graph_generation
step=control_ip_and_network
distance=10

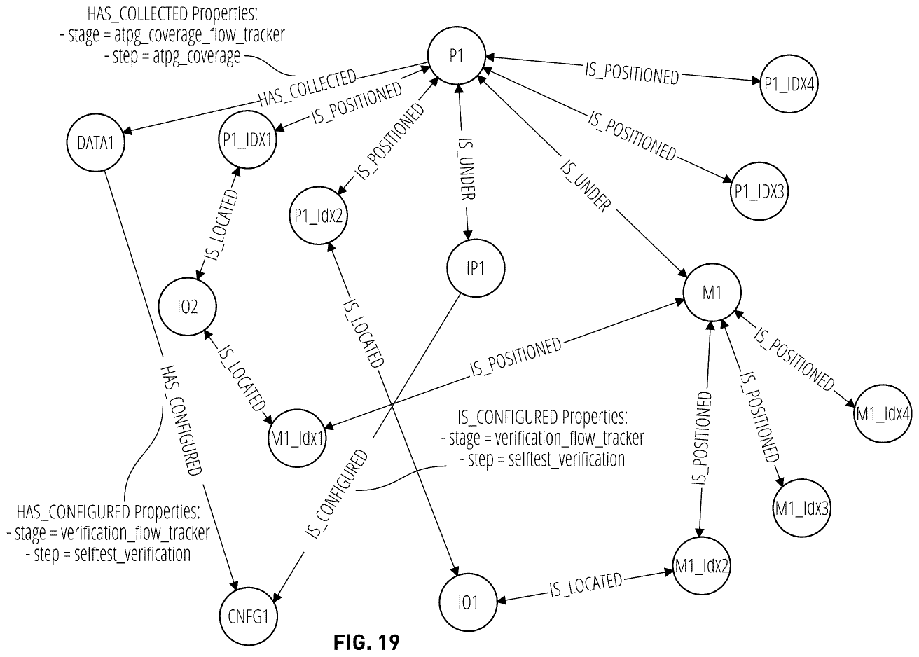

FIG. 19 depicts various VLSI ATPG (Automatic Test Pattern Generation) verification trackers for different IP blocks encoded within a graph structure. ATPG is utilized in the design and testing of integrated circuits to create test patterns for detecting faults in the circuits. ATPG involves generating a set of test vectors that can identify possible defects within the logic gates of a chip.

Information from various stages of the circuit synthesis of each flow stages may be encoded in the graph structure 304 using a particular node type, e.g., a DATA type node. This node may comprise properties for run status, flow configuration, run location, run configuration, and run statistics. With all this information, each flow stage can be track live and run at any time.

A DATA node may be associated with a component using a particular edge type, e.g., a HAS_COLLECTED edge type. For example, in the graph structure depicted in FIG. 19, the Data1 Node may comprise the following properties:
status=Passed
verification_name=selftest_1
run_directory=IP1
logfile_name=ipl_inst
tool_name=tool_1
tool_version=version_A
run_time=360

The graph structure 304 may further encode macro and IP configurations for different production runs of the circuit. These configurations may be encoded using a particular node type, e.g., CNFG. For example, the results of production stages such as Automatic Test Pattern Generation flow stage may be encoded into the graph structure 304 for different configurations. A CNFG node may comprise properties for the settings of the macro and IP options and switches in the configuration it encodes.

A CNFG node for a macro or IP component may be associated with a DATA node using a particular edge type, e.g., a HAS_CONFIGURED edge type.

A CNFG node for a macro or IP component may also be associated with the component node for the macro or IP using a particular edge type, e.g., an IS_CONFIGURED edge type. For example the CNFG node depicted in the graph structure of FIG. 19 may comprise the following properties:
ip_name=Test IP
test_data_register_1=off
test_data_register_2=on

The HAS_COLLECTED, HAS_CONFIGURED, and IS_CONFIGURED edges may each comprise properties encoding flow stage and flow step information for the associated components, for example as depicted in the example graph structure of FIG. 19.

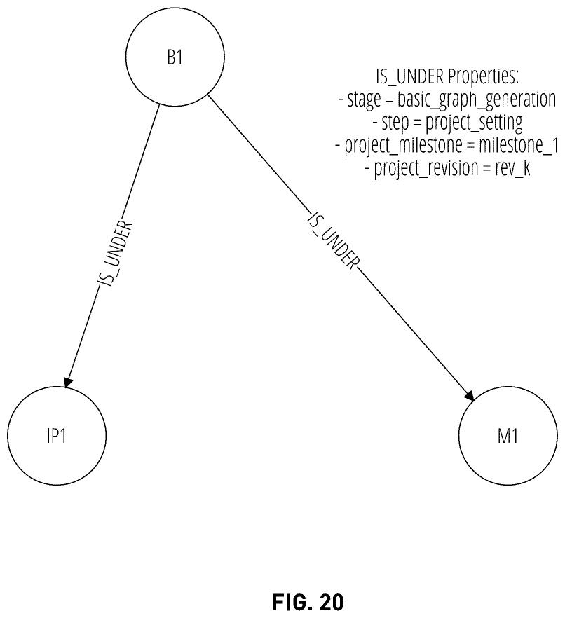

FIG. 20 depicts a graph structure encoding a circuit evolution in accordance with one embodiment. For example project milestone and project revision properties may be encoded in the edges (e.g., IS_UNDER edges as depicted in FIG. 20) in the graph structure for various components of the circuit.

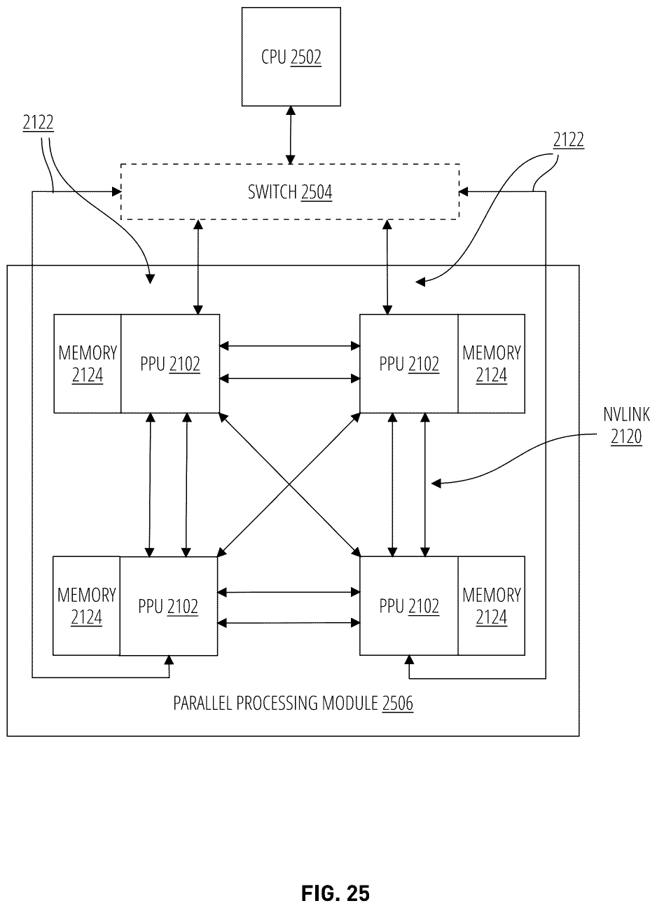

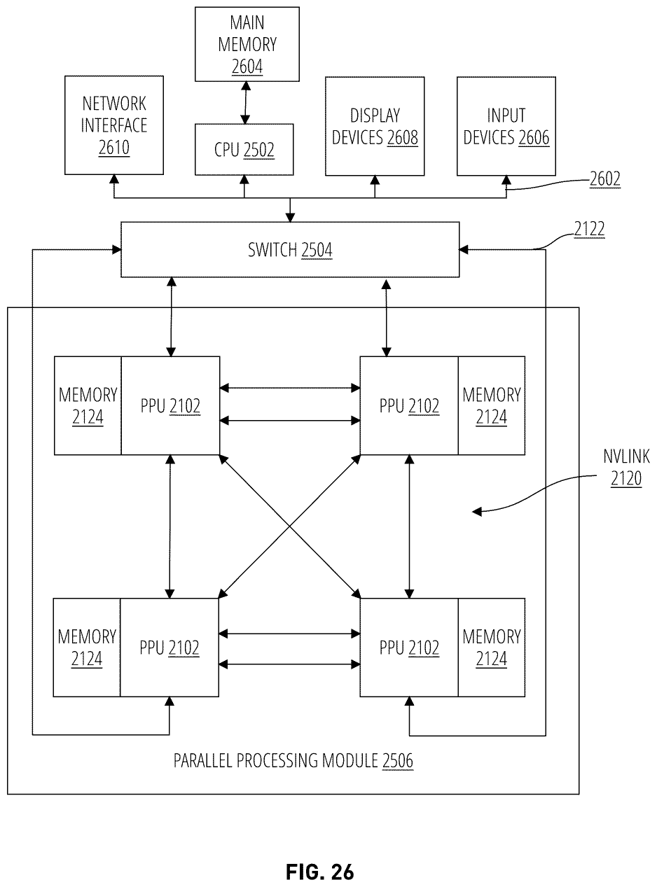

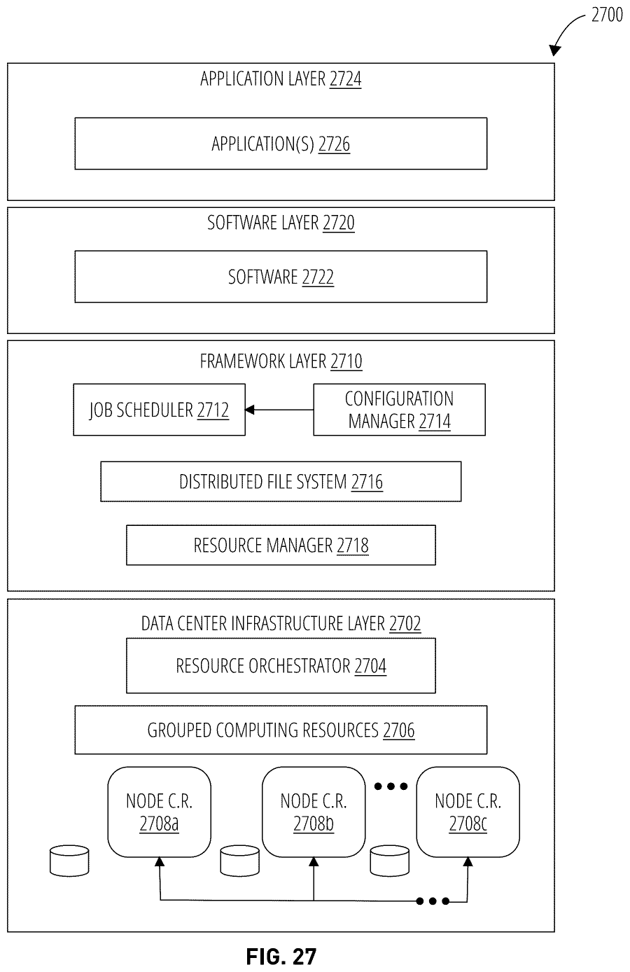

The circuit synthesis mechanisms disclosed herein may be implemented in and/or by computing devices utilizing one or more graphic processing unit (GPU) and/or general purpose data processor (e.g., a ‘central processing unit or CPU). The disclosed mechanisms may be implemented, for example, as machine-readable instructions stored in a non-volatile memory that configure the operation of one or more graphics processing unit and/or central processing unit in a computer system (e.g., FIG. 25, FIG. 26) and/or data center (e.g., FIG. 27). Exemplary architectures will now be described that may be configured to implement the mechanisms disclosed herein.

The following description may use certain acronyms and abbreviations as follows:
“DPC” refers to a “data processing cluster”;
“GPC” refers to a “general processing cluster”;
“I/O” refers to a “input/output”;
“L1 cache” refers to “level one cache”;
“L2 cache” refers to “level two cache”;
“LSU” refers to a “load/store unit”;
“MMU” refers to a “memory management unit”;
“MPC” refers to an “M-pipe controller”;
“PPU” refers to a “parallel processing unit”;
“PROP” refers to a “pre-raster operations unit”;
“ROP” refers to a “raster operations”;
“SFU” refers to a “special function unit”;
“SM” refers to a “streaming multiprocessor”;
“Viewport SCC” refers to “viewport scale, cull, and clip”;
“WDX” refers to a “work distribution crossbar”; and
“XBar” refers to a “crossbar”.

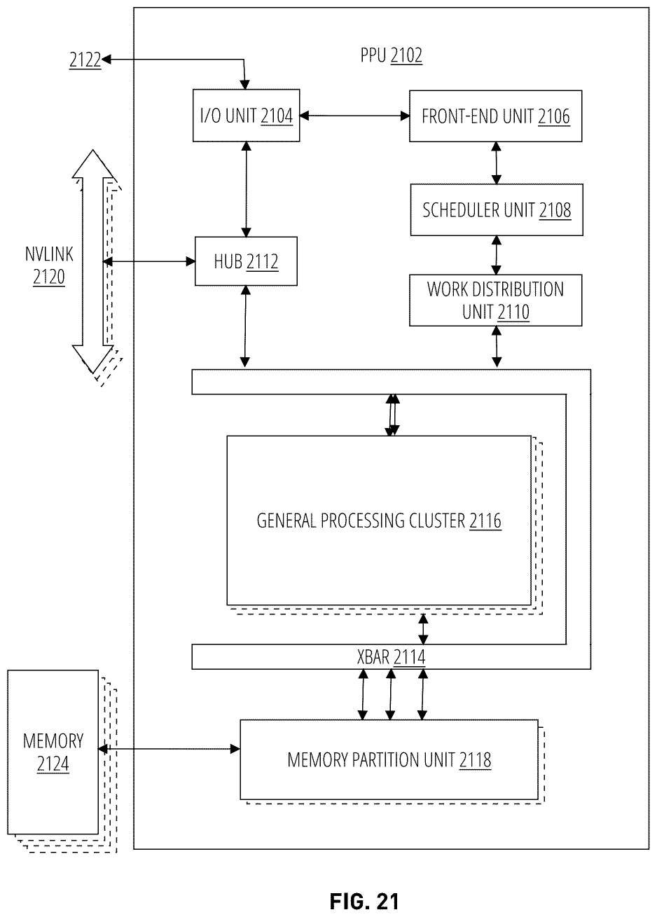

FIG. 21 depicts a parallel processing unit 2102, in accordance with an embodiment. In an embodiment, the parallel processing unit 2102 is a multi-threaded processor that is implemented on one or more integrated circuit devices. The parallel processing unit 2102 is a latency hiding architecture designed to process many threads in parallel. A thread (e.g., a thread of execution) is an instantiation of a set of instructions configured to be executed by the parallel processing unit 2102. In an embodiment, the parallel processing unit 2102 is a graphics processing unit (GPU) configured to implement a graphics rendering pipeline for processing three-dimensional (3D) graphics data in order to generate two-dimensional (2D) image data for display on a display device such as a liquid crystal display (LCD) device. In other embodiments, the parallel processing unit 2102 may be utilized for performing general-purpose computations. While one exemplary parallel processor is provided herein for illustrative purposes, it should be strongly noted that such processor is set forth for illustrative purposes only, and that any processor may be employed to supplement and/or substitute for the same.

One or more parallel processing unit 2102 modules may be configured to accelerate thousands of High Performance Computing (HPC), data center, and machine learning applications. The parallel processing unit 2102 may be configured to accelerate numerous deep learning systems and applications including autonomous vehicle platforms, deep learning, high-accuracy speech, image, and text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and the like.

As shown in FIG. 21, the parallel processing unit 2102 includes an I/O unit 2104, a front-end unit 2106, a scheduler unit 2108, a work distribution unit 2110, a hub 2112, a crossbar 2114, one or more general processing cluster 2116 modules, and one or more memory partition unit 2118 modules. The parallel processing unit 2102 may be connected to a host processor or other parallel processing unit 2102 modules via one or more high-speed NVLink 2120 interconnects. The parallel processing unit 2102 may be connected to a host processor or other peripheral devices via an interconnect 2122. The parallel processing unit 2102 may also be connected to a local memory comprising a number of memory 2124 devices. In an embodiment, the local memory may comprise a number of dynamic random access memory (DRAM) devices. The DRAM devices may be configured as a high-bandwidth memory (HBM) subsystem, with multiple DRAM dies stacked within each device. The memory 2124 may comprise logic to configure the parallel processing unit 2102 to carry out aspects of the techniques disclosed herein.

The NVLink 2120 interconnect enables systems to scale and include one or more parallel processing unit 2102 modules combined with one or more CPUs, supports cache coherence between the parallel processing unit 2102 modules and CPUs, and CPU mastering. Data and/or commands may be transmitted by the NVLink 2120 through the hub 2112 to/from other units of the parallel processing unit 2102 such as one or more copy engines, a video encoder, a video decoder, a power management unit, etc. (not explicitly shown). The NVLink 2120 is described in more detail in conjunction with FIG. 25.

The I/O unit 2104 is configured to transmit and receive communications (e.g., commands, data, etc.) from a host processor (not shown) over the interconnect 2122. The I/O unit 2104 may communicate with the host processor directly via the interconnect 2122 or through one or more intermediate devices such as a memory bridge. In an embodiment, the I/O unit 2104 may communicate with one or more other processors, such as one or more parallel processing unit 2102 modules via the interconnect 2122. In an embodiment, the I/O unit 2104 implements a Peripheral Component Interconnect Express (PCIe) interface for communications over a PCIe bus and the interconnect 2122 is a PCIe bus. In alternative embodiments, the I/O unit 2104 may implement other types of well-known interfaces for communicating with external devices.

The I/O unit 2104 decodes packets received via the interconnect 2122. In an embodiment, the packets represent commands configured to cause the parallel processing unit 2102 to perform various operations. The I/O unit 2104 transmits the decoded commands to various other units of the parallel processing unit 2102 as the commands may specify. For example, some commands may be transmitted to the front-end unit 2106. Other commands may be transmitted to the hub 2112 or other units of the parallel processing unit 2102 such as one or more copy engines, a video encoder, a video decoder, a power management unit, etc. (not explicitly shown). In other words, the I/O unit 2104 is configured to route communications between and among the various logical units of the parallel processing unit 2102.

In an embodiment, a program executed by the host processor encodes a command stream in a buffer that provides workloads to the parallel processing unit 2102 for processing. A workload may comprise several instructions and data to be processed by those instructions. The buffer is a region in a memory that is accessible (e.g., read/write) by both the host processor and the parallel processing unit 2102. For example, the I/O unit 2104 may be configured to access the buffer in a system memory connected to the interconnect 2122 via memory requests transmitted over the interconnect 2122. In an embodiment, the host processor writes the command stream to the buffer and then transmits a pointer to the start of the command stream to the parallel processing unit 2102. The front-end unit 2106 receives pointers to one or more command streams. The front-end unit 2106 manages the one or more streams, reading commands from the streams and forwarding commands to the various units of the parallel processing unit 2102.

The front-end unit 2106 is coupled to a scheduler unit 2108 that configures the various general processing cluster 2116 modules to process tasks defined by the one or more streams. The scheduler unit 2108 is configured to track state information related to the various tasks managed by the scheduler unit 2108. The state may indicate which general processing cluster 2116 a task is assigned to, whether the task is active or inactive, a priority level associated with the task, and so forth. The scheduler unit 2108 manages the execution of a plurality of tasks on the one or more general processing cluster 2116 modules.

The scheduler unit 2108 is coupled to a work distribution unit 2110 that is configured to dispatch tasks for execution on the general processing cluster 2116 modules. The work distribution unit 2110 may track a number of scheduled tasks received from the scheduler unit 2108. In an embodiment, the work distribution unit 2110 manages a pending task pool and an active task pool for each of the general processing cluster 2116 modules. The pending task pool may comprise a number of slots (e.g., 32 slots) that contain tasks assigned to be processed by a particular general processing cluster 2116. The active task pool may comprise a number of slots (e.g., 4 slots) for tasks that are actively being processed by the general processing cluster 2116 modules. As a general processing cluster 2116 finishes the execution of a task, that task is evicted from the active task pool for the general processing cluster 2116 and one of the other tasks from the pending task pool is selected and scheduled for execution on the general processing cluster 2116. If an active task has been idle on the general processing cluster 2116, such as while waiting for a data dependency to be resolved, then the active task may be evicted from the general processing cluster 2116 and returned to the pending task pool while another task in the pending task pool is selected and scheduled for execution on the general processing cluster 2116.

The work distribution unit 2110 communicates with the one or more general processing cluster 2116 modules via crossbar 2114. The crossbar 2114 is an interconnect network that couples many of the units of the parallel processing unit 2102 to other units of the parallel processing unit 2102. For example, the crossbar 2114 may be configured to couple the work distribution unit 2110 to a particular general processing cluster 2116. Although not shown explicitly, one or more other units of the parallel processing unit 2102 may also be connected to the crossbar 2114 via the hub 2112.

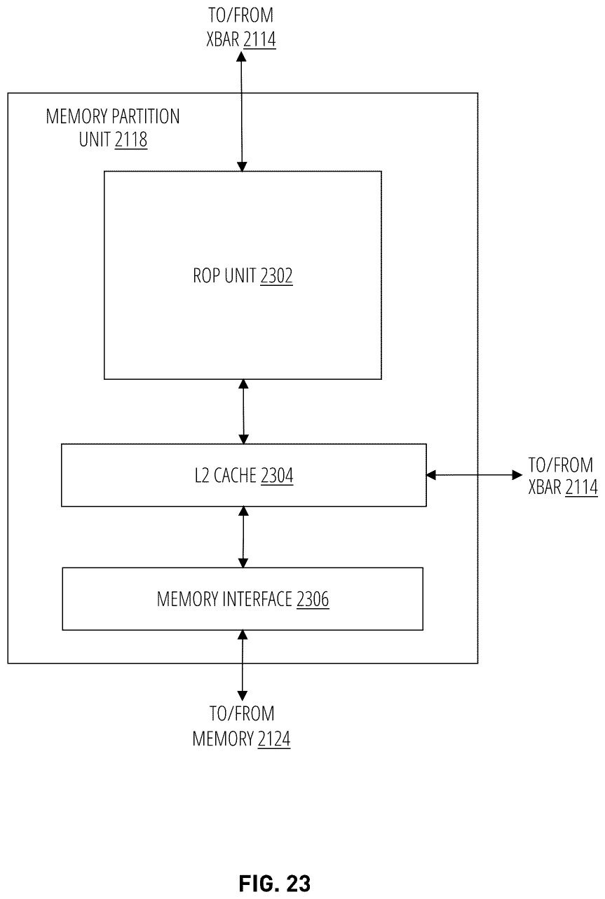

The tasks are managed by the scheduler unit 2108 and dispatched to a general processing cluster 2116 by the work distribution unit 2110. The general processing cluster 2116 is configured to process the task and generate results. The results may be consumed by other tasks within the general processing cluster 2116, routed to a different general processing cluster 2116 via the crossbar 2114, or stored in the memory 2124. The results can be written to the memory 2124 via the memory partition unit 2118 modules, which implement a memory interface for reading and writing data to/from the memory 2124. The results can be transmitted to another parallel processing unit 2102 or CPU via the NVLink 2120. In an embodiment, the parallel processing unit 2102 includes a number U of memory partition unit 2118 modules that is equal to the number of separate and distinct memory 2124 devices coupled to the parallel processing unit 2102. A memory partition unit 2118 will be described in more detail below in conjunction with FIG. 23.

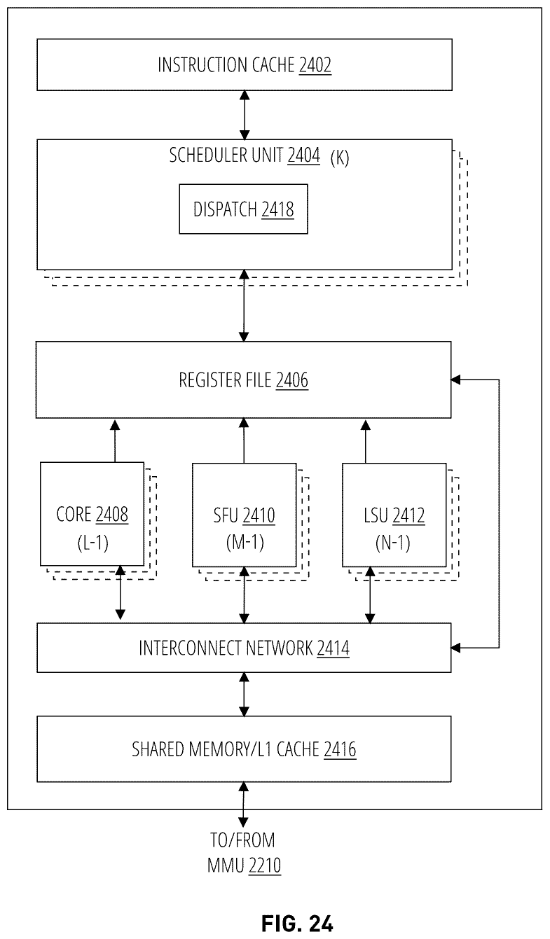

In an embodiment, a host processor executes a driver kernel that implements an application programming interface (API) that enables one or more applications executing on the host processor to schedule operations for execution on the parallel processing unit 2102. In an embodiment, multiple compute applications are simultaneously executed by the parallel processing unit 2102 and the parallel processing unit 2102 provides isolation, quality of service (QoS), and independent address spaces for the multiple compute applications. An application may generate instructions (e.g., API calls) that cause the driver kernel to generate one or more tasks for execution by the parallel processing unit 2102. The driver kernel outputs tasks to one or more streams being processed by the parallel processing unit 2102. Each task may comprise one or more groups of related threads, referred to herein as a warp. In an embodiment, a warp comprises 32 related threads that may be executed in parallel. Cooperating threads may refer to a plurality of threads including instructions to perform the task and that may exchange data through shared memory. Threads and cooperating threads are described in more detail in conjunction with FIG. 24.

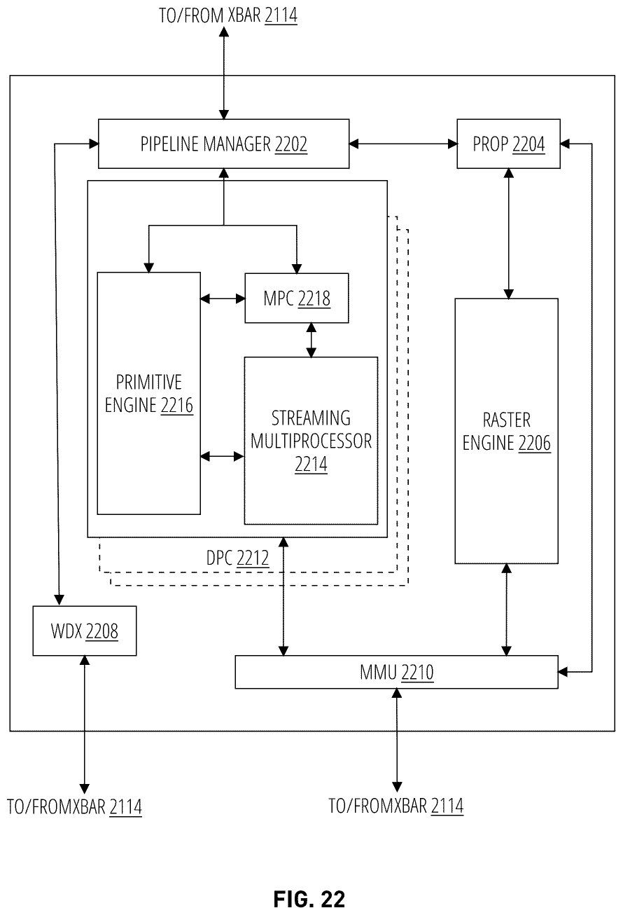

FIG. 22 depicts a general processing cluster 2116 of the parallel processing unit 2102 of FIG. 21, in accordance with an embodiment. As shown in FIG. 22, each general processing cluster 2116 includes a number of hardware units for processing tasks. In an embodiment, each general processing cluster 2116 includes a pipeline manager 2202, a pre-raster operations unit 2204, a raster engine 2206, a work distribution crossbar 2208, a memory management unit 2210, and one or more data processing cluster 2212. It will be appreciated that the general processing cluster 2116 of FIG. 22 may include other hardware units in lieu of or in addition to the units shown in FIG. 22.

In an embodiment, the operation of the general processing cluster 2116 is controlled by the pipeline manager 2202. The pipeline manager 2202 manages the configuration of the one or more data processing cluster 2212 modules for processing tasks allocated to the general processing cluster 2116. In an embodiment, the pipeline manager 2202 may configure at least one of the one or more data processing cluster 2212 modules to implement at least a portion of a graphics rendering pipeline. For example, a data processing cluster 2212 may be configured to execute a vertex shader program on the programmable streaming multiprocessor 2214. The pipeline manager 2202 may also be configured to route packets received from the work distribution unit 2110 to the appropriate logical units within the general processing cluster 2116. For example, some packets may be routed to fixed function hardware units in the pre-raster operations unit 2204 and/or raster engine 2206 while other packets may be routed to the data processing cluster 2212 modules for processing by the primitive engine 2216 or the streaming multiprocessor 2214. In an embodiment, the pipeline manager 2202 may configure at least one of the one or more data processing cluster 2212 modules to implement a neural network model and/or a computing pipeline.

The pre-raster operations unit 2204 is configured to route data generated by the raster engine 2206 and the data processing cluster 2212 modules to a Raster Operations (ROP) unit, described in more detail in conjunction with FIG. 23. The pre-raster operations unit 2204 may also be configured to perform optimizations for color blending, organize pixel data, perform address translations, and the like.

The raster engine 2206 includes a number of fixed function hardware units configured to perform various raster operations. In an embodiment, the raster engine 2206 includes a setup engine, a coarse raster engine, a culling engine, a clipping engine, a fine raster engine, and a tile coalescing engine. The setup engine receives transformed vertices and generates plane equations associated with the geometric primitive defined by the vertices. The plane equations are transmitted to the coarse raster engine to generate coverage information (e.g., an x, y coverage mask for a tile) for the primitive. The output of the coarse raster engine is transmitted to the culling engine where fragments associated with the primitive that fail a z-test are culled, and transmitted to a clipping engine where fragments lying outside a viewing frustum are clipped. Those fragments that survive clipping and culling may be passed to the fine raster engine to generate attributes for the pixel fragments based on the plane equations generated by the setup engine. The output of the raster engine 2206 comprises fragments to be processed, for example, by a fragment shader implemented within a data processing cluster 2212.

Each data processing cluster 2212 included in the general processing cluster 2116 includes an M-pipe controller 2218, a primitive engine 2216, and one or more streaming multiprocessor 2214 modules. The M-pipe controller 2218 controls the operation of the data processing cluster 2212, routing packets received from the pipeline manager 2202 to the appropriate units in the data processing cluster 2212. For example, packets associated with a vertex may be routed to the primitive engine 2216, which is configured to fetch vertex attributes associated with the vertex from the memory 2124. In contrast, packets associated with a shader program may be transmitted to the streaming multiprocessor 2214.

The streaming multiprocessor 2214 comprises a programmable streaming processor that is configured to process tasks represented by a number of threads. Each streaming multiprocessor 2214 is multi-threaded and configured to execute a plurality of threads (e.g., 32 threads) from a particular group of threads concurrently. In an embodiment, the streaming multiprocessor 2214 implements a Single-Instruction, Multiple-Data (SIMD) architecture where each thread in a group of threads (e.g., a warp) is configured to process a different set of data based on the same set of instructions. All threads in the group of threads execute the same instructions. In another embodiment, the streaming multiprocessor 2214 implements a Single-Instruction, Multiple Thread (SIMT) architecture where each thread in a group of threads is configured to process a different set of data based on the same set of instructions, but where individual threads in the group of threads are allowed to diverge during execution. In an embodiment, a program counter, call stack, and execution state is maintained for each warp, enabling concurrency between warps and serial execution within warps when threads within the warp diverge. In another embodiment, a program counter, call stack, and execution state is maintained for each individual thread, enabling equal concurrency between all threads, within and between warps. When execution state is maintained for each individual thread, threads executing the same instructions may be converged and executed in parallel for maximum efficiency. The streaming multiprocessor 2214 will be described in more detail below in conjunction with FIG. 24.

The memory management unit 2210 provides an interface between the general processing cluster 2116 and the memory partition unit 2118. The memory management unit 2210 may provide translation of virtual addresses into physical addresses, memory protection, and arbitration of memory requests. In an embodiment, the memory management unit 2210 provides one or more translation lookaside buffers (TLBs) for performing translation of virtual addresses into physical addresses in the memory 2124.

FIG. 23 depicts a memory partition unit 2118 of the parallel processing unit 2102 of FIG. 21, in accordance with an embodiment. As shown in FIG. 23, the memory partition unit 2118 includes a raster operations unit 2302, a level two cache 2304, and a memory interface 2306. The memory interface 2306 is coupled to the memory 2124. Memory interface 2306 may implement 32, 64, 128, 1024-bit data buses, or the like, for high-speed data transfer. In an embodiment, the parallel processing unit 2102 incorporates U memory interface 2306 modules, one memory interface 2306 per pair of memory partition unit 2118 modules, where each pair of memory partition unit 2118 modules is connected to a corresponding memory 2124 device. For example, parallel processing unit 2102 may be connected to up to Y memory 2124 devices, such as high bandwidth memory stacks or graphics double-data-rate, version 5, synchronous dynamic random access memory, or other types of persistent storage.

In an embodiment, the memory interface 2306 implements an HBM2 memory interface and Y equals half U. In an embodiment, the HBM2 memory stacks are located on the same physical package as the parallel processing unit 2102, providing substantial power and area savings compared with conventional GDDR5 SDRAM systems. In an embodiment, each HBM2 stack includes four memory dies and Y equals 4, with HBM2 stack including two 128-bit channels per die for a total of 8 channels and a data bus width of 1024 bits.

In an embodiment, the memory 2124 supports Single-Error Correcting Double-Error Detecting (SECDED) Error Correction Code (ECC) to protect data. ECC provides higher reliability for compute applications that are sensitive to data corruption. Reliability is especially important in large-scale cluster computing environments where parallel processing unit 2102 modules process very large datasets and/or run applications for extended periods.

In an embodiment, the parallel processing unit 2102 implements a multi-level memory hierarchy. In an embodiment, the memory partition unit 2118 supports a unified memory to provide a single unified virtual address space for CPU and parallel processing unit 2102 memory, enabling data sharing between virtual memory systems. In an embodiment the frequency of accesses by a parallel processing unit 2102 to memory located on other processors is traced to ensure that memory pages are moved to the physical memory of the parallel processing unit 2102 that is accessing the pages more frequently. In an embodiment, the NVLink 2120 supports address translation services allowing the parallel processing unit 2102 to directly access a CPU's page tables and providing full access to CPU memory by the parallel processing unit 2102.

In an embodiment, copy engines transfer data between multiple parallel processing unit 2102 modules or between parallel processing unit 2102 modules and CPUs. The copy engines can generate page faults for addresses that are not mapped into the page tables. The memory partition unit 2118 can then service the page faults, mapping the addresses into the page table, after which the copy engine can perform the transfer. In a conventional system, memory is pinned (e.g., non-pageable) for multiple copy engine operations between multiple processors, substantially reducing the available memory. With hardware page faulting, addresses can be passed to the copy engines without worrying if the memory pages are resident, and the copy process is transparent.

Data from the memory 2124 or other system memory may be fetched by the memory partition unit 2118 and stored in the level two cache 2304, which is located on-chip and is shared between the various general processing cluster 2116 modules. As shown, each memory partition unit 2118 includes a portion of the level two cache 2304 associated with a corresponding memory 2124 device. Lower level caches may then be implemented in various units within the general processing cluster 2116 modules. For example, each of the streaming multiprocessor 2214 modules may implement an L1 cache. The L1 cache is private memory that is dedicated to a particular streaming multiprocessor 2214. Data from the level two cache 2304 may be fetched and stored in each of the L1 caches for processing in the functional units of the streaming multiprocessor 2214 modules. The level two cache 2304 is coupled to the memory interface 2306 and the crossbar 2114.

The raster operations unit 2302 performs graphics raster operations related to pixel color, such as color compression, pixel blending, and the like. The raster operations unit 2302 also implements depth testing in conjunction with the raster engine 2206, receiving a depth for a sample location associated with a pixel fragment from the culling engine of the raster engine 2206. The depth is tested against a corresponding depth in a depth buffer for a sample location associated with the fragment. If the fragment passes the depth test for the sample location, then the raster operations unit 2302 updates the depth buffer and transmits a result of the depth test to the raster engine 2206. It will be appreciated that the number of partition memory partition unit 2118 modules may be different than the number of general processing cluster 2116 modules and, therefore, each raster operations unit 2302 may be coupled to each of the general processing cluster 2116 modules. The raster operations unit 2302 tracks packets received from the different general processing cluster 2116 modules and determines which general processing cluster 1 that a result generated by the raster operations unit 2302 is routed to through the crossbar 2114. Although the raster operations unit 2302 is included within the memory partition unit 2118 in FIG. 23, in other embodiment, the raster operations unit 2302 may be outside of the memory partition unit 2118. For example, the raster operations unit 2302 may reside in the general processing cluster 2116 or another unit.

FIG. 24 illustrates the streaming multiprocessor 2214 of FIG. 22, in accordance with an embodiment. As shown in FIG. 24, the streaming multiprocessor 2214 includes an instruction cache 2402, one or more scheduler unit 2404 modules (e.g., such as scheduler unit 2108), a register file 2406, one or more processing core 2408 modules, one or more special function unit 2410 modules, one or more load/store unit 2412 modules, an interconnect network 2414, and a shared memory/L1 cache 2416.

As described above, the work distribution unit 2110 dispatches tasks for execution on the general processing cluster 2116 modules of the parallel processing unit 2102. The tasks are allocated to a particular data processing cluster 2212 within a general processing cluster 2116 and, if the task is associated with a shader program, the task may be allocated to a streaming multiprocessor 2214. The scheduler unit 2108 receives the tasks from the work distribution unit 2110 and manages instruction scheduling for one or more thread blocks assigned to the streaming multiprocessor 2214. The scheduler unit 2404 schedules thread blocks for execution as warps of parallel threads, where each thread block is allocated at least one warp. In an embodiment, each warp executes 32 threads. The scheduler unit 2404 may manage a plurality of different thread blocks, allocating the warps to the different thread blocks and then dispatching instructions from the plurality of different cooperative groups to the various functional units (e.g., core 2408 modules, special function unit 2410 modules, and load/store unit 2412 modules) during each clock cycle.

Cooperative Groups is a programming model for organizing groups of communicating threads that allows developers to express the granularity at which threads are communicating, enabling the expression of richer, more efficient parallel decompositions. Cooperative launch APIs support synchronization amongst thread blocks for the execution of parallel algorithms. Conventional programming models provide a single, simple construct for synchronizing cooperating threads: a barrier across all threads of a thread block (e.g., the syncthreads( ) function). However, programmers would often like to define groups of threads at smaller than thread block granularities and synchronize within the defined groups to enable greater performance, design flexibility, and software reuse in the form of collective group-wide function interfaces.

Cooperative Groups enables programmers to define groups of threads explicitly at sub-block (e.g., as small as a single thread) and multi-block granularities, and to perform collective operations such as synchronization on the threads in a cooperative group. The programming model supports clean composition across software boundaries, so that libraries and utility functions can synchronize safely within their local context without having to make assumptions about convergence. Cooperative Groups primitives enable new patterns of cooperative parallelism, including producer-consumer parallelism, opportunistic parallelism, and global synchronization across an entire grid of thread blocks.

A dispatch 2418 unit is configured within the scheduler unit 2404 to transmit instructions to one or more of the functional units. In one embodiment, the scheduler unit 2404 includes two dispatch 2418 units that enable two different instructions from the same warp to be dispatched during each clock cycle. In alternative embodiments, each scheduler unit 2404 may include a single dispatch 2418 unit or additional dispatch 2418 units.

Each streaming multiprocessor 2214 includes a register file 2406 that provides a set of registers for the functional units of the streaming multiprocessor 2214. In an embodiment, the register file 2406 is divided between each of the functional units such that each functional unit is allocated a dedicated portion of the register file 2406. In another embodiment, the register file 2406 is divided between the different warps being executed by the streaming multiprocessor 2214. The register file 2406 provides temporary storage for operands connected to the data paths of the functional units.

Each streaming multiprocessor 2214 comprises L processing core 2408 modules. In an embodiment, the streaming multiprocessor 2214 includes a large number (e.g., 128, etc.) of distinct processing core 2408 modules. Each core 2408 may include a fully-pipelined, single-precision, double-precision, and/or mixed precision processing unit that includes a floating point arithmetic logic unit and an integer arithmetic logic unit. In an embodiment, the floating point arithmetic logic units implement the IEEE 754-2008 standard for floating point arithmetic. In an embodiment, the core 2408 modules include 64 single-precision (32-bit) floating point cores, 64 integer cores, 32 double-precision (64-bit) floating point cores, and 8 tensor cores.

Tensor cores configured to perform matrix operations, and, in an embodiment, one or more tensor cores are included in the core 2408 modules. In particular, the tensor cores are configured to perform deep learning matrix arithmetic, such as convolution operations for neural network training and inferencing. In an embodiment, each tensor core operates on a 4×4 matrix and performs a matrix multiply and accumulate operation D=A′B+C, where A, B, C, and D are 4×4 matrices.

In an embodiment, the matrix multiply inputs A and B are 16-bit floating point matrices, while the accumulation matrices C and D may be 16-bit floating point or 32-bit floating point matrices. Tensor Cores operate on 16-bit floating point input data with 32-bit floating point accumulation. The 16-bit floating point multiply requires 64 operations and results in a full precision product that is then accumulated using 32-bit floating point addition with the other intermediate products for a 4×4×4 matrix multiply. In practice, Tensor Cores are used to perform much larger two-dimensional or higher dimensional matrix operations, built up from these smaller elements. An API, such as CUDA 9 C++ API, exposes specialized matrix load, matrix multiply and accumulate, and matrix store operations to efficiently use Tensor Cores from a CUDA-C++ program. At the CUDA level, the warp-level interface assumes 16×16 size matrices spanning all 32 threads of the warp.

Each streaming multiprocessor 2214 also comprises M special function unit 2410 modules that perform special functions (e.g., attribute evaluation, reciprocal square root, and the like). In an embodiment, the special function unit 2410 modules may include a tree traversal unit configured to traverse a hierarchical tree data structure. In an embodiment, the special function unit 2410 modules may include texture unit configured to perform texture map filtering operations. In an embodiment, the texture units are configured to load texture maps (e.g., a 2D array of texels) from the memory 2124 and sample the texture maps to produce sampled texture values for use in shader programs executed by the streaming multiprocessor 2214. In an embodiment, the texture maps are stored in the shared memory/L1 cache 2416. The texture units implement texture operations such as filtering operations using mip-maps (e.g., texture maps of varying levels of detail). In an embodiment, each streaming multiprocessor 2214 includes two texture units.

Each streaming multiprocessor 2214 also comprises N load/store unit 2412 modules that implement load and store operations between the shared memory/L1 cache 2416 and the register file 2406. Each streaming multiprocessor 2214 includes an interconnect network 2414 that connects each of the functional units to the register file 2406 and the load/store unit 2412 to the register file 2406 and shared memory/L1 cache 2416. In an embodiment, the interconnect network 2414 is a crossbar that can be configured to connect any of the functional units to any of the registers in the register file 2406 and connect the load/store unit 2412 modules to the register file 2406 and memory locations in shared memory/L1 cache 2416.

The shared memory/L1 cache 2416 is an array of on-chip memory that allows for data storage and communication between the streaming multiprocessor 2214 and the primitive engine 2216 and between threads in the streaming multiprocessor 2214. In an embodiment, the shared memory/L1 cache 2416 comprises 128 KB of storage capacity and is in the path from the streaming multiprocessor 2214 to the memory partition unit 2118. The shared memory/L1 cache 2416 can be used to cache reads and writes. One or more of the shared memory/L1 cache 2416, level two cache 2304, and memory 2124 are backing stores.

Combining data cache and shared memory functionality into a single memory block provides the best overall performance for both types of memory accesses. The capacity is usable as a cache by programs that do not use shared memory. For example, if shared memory is configured to use half of the capacity, texture and load/store operations can use the remaining capacity. Integration within the shared memory/L1 cache 2416 enables the shared memory/L1 cache 2416 to function as a high-throughput conduit for streaming data while simultaneously providing high-bandwidth and low-latency access to frequently reused data.

When configured for general purpose parallel computation, a simpler configuration can be used compared with graphics processing. Specifically, the fixed function graphics processing units shown in FIG. 21, are bypassed, creating a much simpler programming model. In the general purpose parallel computation configuration, the work distribution unit 2110 assigns and distributes blocks of threads directly to the data processing cluster 2212 modules. The threads in a block execute the same program, using a unique thread ID in the calculation to ensure each thread generates unique results, using the streaming multiprocessor 2214 to execute the program and perform calculations, shared memory/L1 cache 2416 to communicate between threads, and the load/store unit 2412 to read and write global memory through the shared memory/L1 cache 2416 and the memory partition unit 2118. When configured for general purpose parallel computation, the streaming multiprocessor 2214 can also write commands that the scheduler unit 2108 can use to launch new work on the data processing cluster 2212 modules.

The parallel processing unit 2102 may be included in a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, and the like. In an embodiment, the parallel processing unit 2102 is embodied on a single semiconductor substrate. In another embodiment, the parallel processing unit 2102 is included in a system-on-a-chip (SoC) along with one or more other devices such as additional parallel processing unit 2102 modules, the memory 2124, a reduced instruction set computer (RISC) CPU, a memory management unit (MMU), a digital-to-analog converter (DAC), and the like.

In an embodiment, the parallel processing unit 2102 may be included on a graphics card that includes one or more memory devices. The graphics card may be configured to interface with a PCIe slot on a motherboard of a desktop computer. In yet another embodiment, the parallel processing unit 2102 may be an integrated graphics processing unit (iGPU) or parallel processor included in the chipset of the motherboard.

Systems with multiple GPUs and CPUs are used in a variety of industries as developers expose and leverage more parallelism in applications such as artificial intelligence computing. High-performance GPU-accelerated systems with tens to many thousands of compute nodes are deployed in data centers, research facilities, and supercomputers to solve ever larger problems. As the number of processing devices within the high-performance systems increases, the communication and data transfer mechanisms need to scale to support the increased bandwidth.

FIG. 25 is a conceptual diagram of a processing system implemented using the parallel processing unit 2102 of FIG. 21, in accordance with an embodiment. The processing system includes a central processing unit 2502, an switch 2504, and multiple parallel processing unit 2102 modules each and respective memory 2124 modules. The switch 2504 is depicted with dashed lines, indicating that it is optional in some embodiments.

The NVLink 2120 provides high-speed communication links between each of the parallel processing unit 2102 modules. Although a particular number of NVLink 2120 and interconnect 2122 connections are illustrated in FIG. 25, the number of connections to each parallel processing unit 2102 and the central processing unit 2502 may vary. The switch 2504 interfaces between the interconnect 2122 and the central processing unit 2502. The parallel processing unit 2102 modules, memory 2124 modules, and NVLink 2120 connections may be situated on a single semiconductor platform to form a parallel processing module 2506. In an embodiment, the switch 2504 supports two or more protocols to interface between various different connections and/or links.

In another embodiment (not shown), the NVLink 2120 provides one or more high-speed communication links between each of the parallel processing unit modules (parallel processing unit 2102, parallel processing unit 2102, parallel processing unit 2102, and parallel processing unit 2102) and the central processing unit 2502 and the switch 2504 (when present) interfaces between the interconnect 2122 and each of the parallel processing unit modules. The parallel processing unit modules, memory 2124 modules, and interconnect 2122 may be situated on a single semiconductor platform to form a parallel processing module 2506. In yet another embodiment (not shown), the interconnect 2122 provides one or more communication links between each of the parallel processing unit modules and the central processing unit 2502 and the switch 2504 interfaces between each of the parallel processing unit modules using the NVLink 2120 to provide one or more high-speed communication links between the parallel processing unit modules. In another embodiment (not shown), the NVLink 2120 provides one or more high-speed communication links between the parallel processing unit modules and the central processing unit 2502 through the switch 2504. In yet another embodiment (not shown), the interconnect 2122 provides one or more communication links between each of the parallel processing unit modules directly. One or more of the NVLink 2120 high-speed communication links may be implemented as a physical NVLink interconnect or either an on-chip or on-die interconnect using the same protocol as the NVLink 2120.

In the context of the present description, a single semiconductor platform may refer to a sole unitary semiconductor-based integrated circuit fabricated on a die or chip. It should be noted that the term single semiconductor platform may also refer to multi-chip modules with increased connectivity which simulate on-chip operation and make substantial improvements over utilizing a conventional bus implementation. Of course, the various circuits or devices may also be situated separately or in various combinations of semiconductor platforms per the desires of the user. Alternately, the parallel processing module 2506 may be implemented as a circuit board substrate and each of the parallel processing unit modules and/or memory 2124 modules may be packaged devices. In an embodiment, the central processing unit 2502, switch 2504, and the parallel processing module 2506 are situated on a single semiconductor platform.

In an embodiment, each parallel processing unit module includes six NVLink 2120 interfaces (as shown in FIG. 25, five NVLink 2120 interfaces are included for each parallel processing unit module). The NVLink 2120 may be operated exclusively for PPU-to-PPU communication as shown in FIG. 25, or some combination of PPU-to-PPU and PPU-to-CPU, when the central processing unit 2502 also includes one or more NVLink 2120 interfaces.

In an embodiment, the NVLink 2120 allows direct load/store/atomic access from the central processing unit 2502 to each parallel processing unit module's memory 2124. In an embodiment, the NVLink 2120 supports coherency operations, allowing data read from the memory 2124 modules to be stored in the cache hierarchy of the central processing unit 2502, reducing cache access latency for the central processing unit 2502. In an embodiment, the NVLink 2120 includes support for Address Translation Services (ATS), enabling the parallel processing unit module to directly access page tables within the central processing unit 2502. One or more of the NVLink 2120 may also be configured to operate in a low-power mode.

FIG. 26 depicts an exemplary processing system in which the various architecture and/or functionality of the various previous embodiments may be implemented. As shown, an exemplary processing system is provided including at least one central processing unit 2502 that is connected to a communications bus 2602. The communication communications bus 2602 may be implemented using any suitable protocol, such as PCI (Peripheral Component Interconnect), PCI-Express, AGP (Accelerated Graphics Port), HyperTransport, or any other bus or point-to-point communication protocol(s). The exemplary processing system also includes a main memory 2604. Control logic (software) and data are stored in the main memory 2604 which may take the form of random access memory (RAM).

The exemplary processing system also includes input devices 2606, the parallel processing module 2506, and display devices 2608, e.g. a conventional CRT (cathode ray tube), LCD (liquid crystal display), LED (light emitting diode), plasma display or the like. User input may be received from the input devices 2606, e.g., keyboard, mouse, touchpad, microphone, and the like. Each of the foregoing modules and/or devices may even be situated on a single semiconductor platform to form the exemplary processing system. Alternately, the various modules may also be situated separately or in various combinations of semiconductor platforms per the desires of the user.

Further, the exemplary processing system may be coupled to a network (e.g., a telecommunications network, local area network (LAN), wireless network, wide area network (WAN) such as the Internet, peer-to-peer network, cable network, or the like) through a network interface 2610 for communication purposes.

The exemplary processing system may also include a secondary storage (not shown). The secondary storage includes, for example, a hard disk drive and/or a removable storage drive, representing a floppy disk drive, a magnetic tape drive, a compact disk drive, digital versatile disk (DVD) drive, recording device, universal serial bus (USB) flash memory. The removable storage drive reads from and/or writes to a removable storage unit in a well-known manner.

Computer programs, or computer control logic algorithms, may be stored in the main memory 2604 and/or the secondary storage. Such computer programs, when executed, enable the exemplary processing system to perform various functions. The main memory 2604, the storage, and/or any other storage are possible examples of computer-readable media.

The architecture and/or functionality of the various previous figures may be implemented in the context of a general computer system, a circuit board system, a game console system dedicated for entertainment purposes, an application-specific system, and/or any other desired system. For example, the exemplary processing system may take the form of a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, a mobile phone device, a television, workstation, game consoles, embedded system, and/or any other type of logic.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

FIG. 27 depicts an exemplary data center 2700, in accordance with at least one embodiment. In at least one embodiment, data center 2700 includes, without limitation, a data center infrastructure layer 2702, a framework layer 2710, a software layer 2720, and an application layer 2724.

In at least one embodiment, as depicted in FIG. 27, data center infrastructure layer 2702 may include a resource orchestrator 2704, grouped computing resources 2706, and node computing resources (node C.R.s) 2708a, 2708b, 2708c, where “N” represents any whole, positive integer. In at least one embodiment, node computing resources may include, but are not limited to, any number of central processing units (CPUs) or other processors (including accelerators, field programmable gate arrays (FPGAs), graphics processors, etc.), memory devices (e.g., dynamic read-only memory), storage devices (e.g., solid state or disk drives), network input/output (NW I/O) devices, network switches, virtual machines (VMs), power modules, and cooling modules, etc. In at least one embodiment, one or more node computing resources from among node computing resources 2708a, 2708b, 2708c may be a server having one or more of the above-mentioned computing resources.

In at least one embodiment, grouped computing resources 2706 may include separate groupings of node computing resources housed within one or more racks (not shown), or many racks housed in data centers at various geographical locations (also not shown). Separate groupings of node computing resources within grouped computing resources 2706 may include grouped compute network, memory, or storage resources that may be configured or allocated to support one or more workloads. In at least one embodiment, several node computing resources including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 2704 may configure or otherwise control one or more node computing resources 2708a, 2708b, 2708c and/or grouped computing resources 2706. In at least one embodiment, resource orchestrator 2704 may include a software design infrastructure (“SDI”) management entity for data center 2700. In at least one embodiment, resource orchestrator 2704 may include hardware, software, or some combination thereof.

In at least one embodiment, as depicted in FIG. 27, framework layer 2710 includes, without limitation, a job scheduler 2712, a configuration manager 2714, a resource manager 2718, and a distributed file system 2716. In at least one embodiment, framework layer 2710 may include a framework to support software 2722 of software layer 2720 and/or one or more application(s) 2726 of application layer 220. In at least one embodiment, software 2722 or application(s) 2726 may respectively include web-based service software or applications, such as those provided by Amazon Web Services, Google Cloud, and Microsoft Azure. In at least one embodiment, framework layer 2710 may be, but is not limited to, a type of free and open-source software web application framework such as Apache SPARK™ (hereinafter “Spark) that may utilize a distributed file system 2716 for large-scale data processing (e.g., “big data”). In at least one embodiment, job scheduler 2712 may include a Spark driver to facilitate scheduling of workloads supported by various layers of data center 2700. In at least one embodiment, configuration manager 2714 may be capable of configuring different layers such as software layer 2720 and framework layer 2710, including Spark and distributed file system 2716 for supporting large-scale data processing. In at least one embodiment, resource manager 2718 may be capable of managing clustered or grouped computing resources mapped to or allocated for support of distributed file system 2716 and job scheduler 2712. In at least one embodiment, clustered or grouped computing resources may include grouped computing resources 2706 at data center infrastructure layer 2702. In at least one embodiment, resource manager 2718 may coordinate with resource orchestrator 2704 to manage these mapped or allocated computing resources.

In at least one embodiment, software 2722 included in software layer 2720 may include software used by at least portions of node computing resources 2708a, 2708b, 2708c, grouped computing resources 2706, and/or distributed file system 2716 of framework layer 2710. One or more types of software may include, but are not limited to, Internet web page search software, e-mail virus scan software, database software, and streaming video content software.

In at least one embodiment, application(s) 2726 included in application layer 2724 may include one or more types of applications used by at least portions of node computing resources 2708a, 2708b, 2708c, grouped computing resources 2706, and/or distributed file system 2716 of framework layer 2710. In at least one or more types of applications may include, without limitation, Compute Unified Device Architecture (CUDA) applications, 5G network applications, artificial intelligence applications, data center applications, and/or variations thereof.

In at least one embodiment, any of configuration manager 2714, resource manager 2718, and resource orchestrator 2704 may implement any number and type of self-modifying actions based on any amount and type of data acquired in any technically feasible fashion. In at least one embodiment, self-modifying actions may relieve a data center operator of data center 2700 from making possibly bad configuration decisions and possibly avoiding underutilized and/or poorly performing portions of a data center.

### LISTING OF DRAWING ELEMENTS

102 circuit structure
202 design database
204 library database
206 IP/Macro database
302 graph generator
304 graph structure
306 neural network configurator
308 filter
310 filtered graph
312 neural network
314 control panel
316 transformer
318 collateral files
320 internal pre-silicon synthesis
322 external pre-silicon synthesis
324 post-silicon synthesis
402 graph neural network
404 graph embedding
406 graph neural network
408 graph neural network
410 activation
412 activation
414 embedding system
416 input tensors
1002 port
1004 port
2102 parallel processing unit
2104 I/O unit
2106 front-end unit
2108 scheduler unit
2110 work distribution unit
2112 hub
2114 crossbar
2116 general processing cluster
2118 memory partition unit
2120 NVLink
2122 interconnect
2124 memory
2202 pipeline manager
2204 pre-raster operations unit
2206 raster engine
2208 work distribution crossbar
2210 memory management unit
2212 data processing cluster
2214 streaming multiprocessor
2216 primitive engine
2218 M-pipe controller
2302 raster operations unit
2304 level two cache
2306 memory interface
2402 instruction cache
2404 scheduler unit
2406 register file
2408 core
2410 special function unit
2412 load/store unit
2414 interconnect network
2416 shared memory/L1 cache
2418 dispatch
2502 central processing unit
2504 switch
2506 parallel processing module
2602 communications bus
2604 main memory
2606 input devices
2608 display devices
2610 network interface
2700 data center
2702 data center infrastructure layer
2704 resource orchestrator
2706 grouped computing resources
2708a node computing resource
2708b node computing resource
2708c node computing resource
2710 framework layer
2712 job scheduler
2714 configuration manager
2716 distributed file system
2718 resource manager
2720 software layer
2722 software
2724 application layer
2726 application(s)

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the disclosure as claimed. The scope of inventive subject matter is not limited to the depicted embodiments but is rather set forth in the following Claims.

What is claimed is:

1. A system for synthesizing a circuit, the system comprising:
an encoder configured to convert outputs of an Electronic Design Automation (EDA) system into a first graph structure encoding physical characteristics of the circuit;
a first neural network comprising a plurality of filtering layers, the first neural network configured to reduce the first graph structure into a second graph structure; and
a second neural network configured to transform the reduced graph structure into updates to the first graph structure.

2. The system of claim 1, wherein the first neural network is configured to filter the first graph structure based on component gap sizes in the circuit and component congestion in the circuit.

3. The system of claim 1, wherein the first neural network comprises a graph neural network configured to transform an embedding of the reduced graph structure into training tensors for the second neural network.

4. The system of claim 1, wherein the first neural network comprises a plurality of graph neural networks.

5. The system of claim 4, wherein the first neural network further comprises a plurality of activation layers interposed between the graph neural networks.

6. The system of claim 5, configured to train coefficients of the activation layers using outputs of the second neural network.

7. The system of claim 6, wherein the coefficients represent partition gaps and core gaps between macros of the circuit.

8. The system of claim 5, wherein the activation layers comprise ReLU (rectified linear unit) layers.

9. The system of claim 1, wherein the first graph structure comprises nodes representing index positions for partitions and macro blocks of the circuit.

10. The system of claim 1, wherein the first graph structure comprises nodes for components of the circuit, the nodes for the components comprising power domain settings.

11. The system of claim 1, wherein the first graph structure comprises nodes representing inputs to and outputs from the circuit.

12. The system of claim 11, wherein the first graph structure comprises edges representing interfaces to the macro blocks and partitions.

13. The system of claim 1, wherein the first graph structure comprises edges representing routes in the circuit.

14. A circuit synthesis control process comprising:
encoding file outputs of an Electronic Design Automation (EDA) system into a first graph structure comprising characteristics of a circuit;
filtering the first graph structure through a first neural network to generate a second graph structure; and
transforming the second graph structure through a second neural network to generate updates to the first graph structure.

15. The process of claim 14, wherein the first neural network filters the first graph structure based on component gaps in the circuit.

16. The process of claim 14, wherein the first neural network filters the first graph structure based on component congestion in the circuit.

17. The process of claim 14, wherein filtering the first graph structure comprises processing the first graph structure through a plurality of graph neural networks.

18. The process of claim 17, further comprising:
configuring activation coefficients of the first neural network based on outputs of the second neural network.

19. The system of claim 18, wherein the coefficients represent partition gaps and core gaps between macros of the circuit.

20. A non-transitory machine-readable medium comprising instructions that, when applied to one or more graphics processing unit of a computer system, configure the computer system to:
encode collateral files generated by an Electronic Design Automation (EDA) system into a first graph structure comprising characteristics of a circuit;
filter the first graph structure through a first neural network to generate a second graph structure; and
transform the second graph structure through a second neural network to generate updates to the first graph structure.
